(19) United States
(12) Patent Application Publication
(10) Pub. No.: US 2025/0220998 A1
(43) Pub. Date: Jul. 3, 2025

(54) III-N SEMICONDUCTOR DEVICE WITH SUBSTRATE CONTACT

(71) Applicant: Texas Instruments Incorporated, Dallas, TX (US)

(72) Inventors: Takayuki Enda, Aizuwakamatsu-shi Fukushima (JP); Masahiko Higashi, Aizuwakamatsu-shi Fukushima (JP)

(21) Appl. No.: 18/400,672

(22) Filed: Dec. 29, 2023

(51) Int. Cl. H01L 29/20; H01L 21/02; H01L 29/40; H01L 29/49

(52) U.S. Cl. CPC H10D 62/8503; H01L 21/0254; H10D 64/01; H10D 64/66

(57) ABSTRACT

A semiconductor device, comprising, a semiconductor substrate, a III-N semiconductor layer over the semiconductor substrate, a contact pad on the III-N semiconductor layer, a first dielectric layer over the III-N semiconductor layer, a first metal contact through the first dielectric layer and contacting the contact pad, and a second metal contact, including a first side contacting the first dielectric layer and a second side contacting a second dielectric layer, and contacting the semiconductor substrate.

### CROSS-REFERENCE TO RELATED APPLICATION

Not Applicable.

### TECHNICAL AREA

Described examples relate to a semiconductor device and fabrication, and more particularly, but not exclusively, to a III-N device, such as gallium nitride (GaN) or others (e.g., aluminum nitride, aluminum gallium nitride) with a substrate contact structure and/or methodology.

### BACKGROUND

Semiconductor devices, such as integrated circuit (IC) devices, using III-N semiconductors such as GaN, are now providing designers, and IC users, with a practical and viable alternative to silicon metal-oxide-semiconductor field effect transistors (MOSFETS). GaN devices operate faster with high-speed switching capability in the MHz range, are smaller allowing higher power density systems, and are more efficient, allowing lower switching energy and reverse recovery losses.

In some examples, a GaN device is formed with one or more GaN layers atop a silicon substrate. In this approach and for proper operation, an electrical contact or contacts is desirable from higher layers in the device to the silicon substrate. For example, this contact(s) permits maintaining constant bias in the silicon substrate and enabling the GaN device(s) to handle higher currents. Integrating the substrate contacts to the silicon substrates while attaining desired circuit density has been challenging.

### SUMMARY

In an example, there is a semiconductor device, comprising, a semiconductor substrate, a III-N semiconductor layer over the semiconductor substrate, a contact pad on the III-N semiconductor layer, a first dielectric layer over the III-N semiconductor layer, a first metal contact through the first dielectric layer and contacting the contact pad, and a second metal contact, including a first side contacting the first dielectric layer and a second side contacting a second dielectric layer, and contacting the semiconductor substrate.

Other aspects are also described and claimed.

### BRIEF DESCRIPTION OF THE DRAWINGS

FIGS. 1 through 4 are cross-section views representing successive fabrication stages and resultant structures of a semiconductor device.

FIGS. 5A and 5B are cross-section views representing a first alternative process sequence following FIG. 4.

FIG. 5C is a cross-section view representing an alternative process sequence to FIG. 5B.

FIGS. 6A and 6B are cross-section views representing a second alternative process sequence following FIG. 4.

FIG. 6C is a cross-section view representing an alternative process sequence to FIG. 6B.

FIG. 7 is a flow diagram of an example method summarizing various of the steps for manufacturing the semiconductor device.

### DETAILED DESCRIPTION

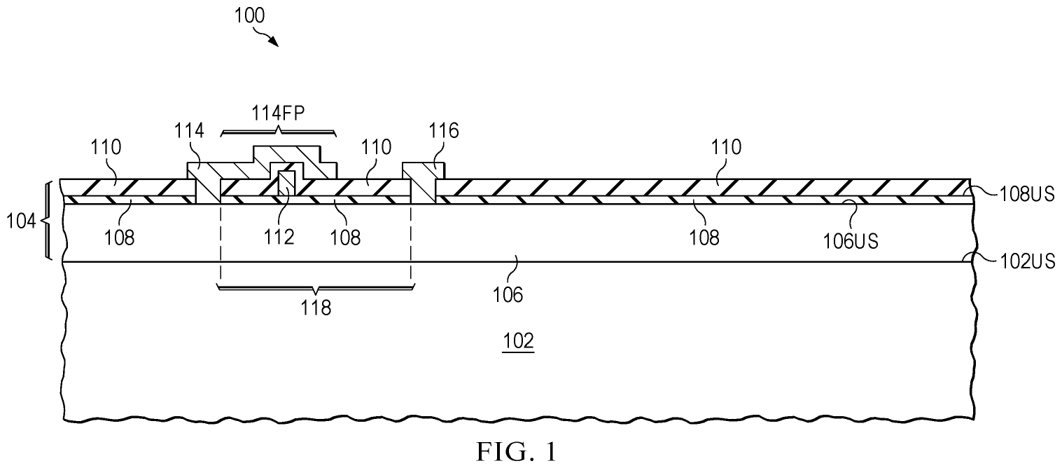

Examples are described with reference to the attached figures, which may not be drawn to scale. Several aspects are described with reference to example applications for illustration, in which like features correspond to like reference numbers. In FIG. 1 and various later figures, cross-sectional views are shown in an x-y (horizontal-vertical) plane but should be understood to also have features in the z-dimension, understood to be extending in a direction in and out of the illustrated image plane. The directional references are for purposes of relative placement, but such terms are not intended to be restrictive as the device may be rotated in space and thereby change absolute, but not relative, references. Numerous specific details, relationships, and methods are set forth to provide an understanding, but the scope is not necessarily limited by the illustrated ordering of acts or events, as some acts may occur in different orders and/or concurrently with other acts or events. Further, not all illustrated acts or events may be required to implement a methodology in accordance with one or more examples.

The examples relate to semiconductor device fabrication, and more particularly but not exclusively to a semiconductor device 100 that may be implemented as a III-N (e.g., GaN) field effect transistor (FET). The GaN FET may be formed at a same time and sharing certain process steps with other devices. This document provides examples that may improve on certain concepts, as detailed below. While such examples may be expected to provide various advantages, no particular result is a requirement unless explicitly recited in a particular claim.

FIG. 1 is a cross-section and partial view of the semiconductor device 100, e.g. a portion of an IC. The semiconductor device 100 includes a semiconductor substrate 102, for example as part of a silicon wafer. Such a wafer typically includes multiple locations, each corresponding to a same or different IC on the wafer, so the illustration of FIG. 1 (and later figures) can be repeated in each wafer IC location. The wafer typically provides either a P-type or N-type semiconductor, and the semiconductor substrate 102 can represent a portion of the bulk wafer or a region (e.g., a well and/or buried layer and/or epitaxial layer) formed in connection with the wafer.

As now introduced with FIG. 1 and detailed in the remaining figures, a GaN device, which in the illustrated example is GaN FET, is formed in connection with the substrate 102 and generally with a lateral layout. Relatedly, a layer stack 104 is formed along an upper surface 102US of the substrate 102, and by example is shown to include three layers. A first layer in the layer stack 104 is a III-N layer 106, for example implemented as a GaN layer 106 (sometimes referred to as a GaN buffer), formed at least in part, aligned along a plane (e.g., along an upper surface 102US of the substrate 102). The GaN layer 106 may be formed by a sequence of vapor phase epitaxial processes, and may have a thickness in a range from 1.2 μm to 3.5 μm, depending in part on the maximum operating potential of the GaN FET. A second layer in the layer stack 104 is an aluminum gallium nitride (AlGaN) barrier layer 108, formed along an upper surface 106US of the GaN layer 106. The AlGaN barrier layer 108 may have a thickness in a range from 5 nm to 30 nm. A third layer in the layer stack 104 is a passivation layer 110, such as a dielectric layer (e.g., silicon nitride (SiN)), formed along an upper surface 108US of the AlGaN barrier layer 108. The passivation layer 110 may be formed by a low pressure chemical vapor deposition (LPCVD) process, and with a thickness in a range from 20 nm to 100 nm. The passivation layer 110 also may be referred to as a first pre-metal dielectric (PMD) layer.

FIG. 1 also illustrates three conductive terminals of the GaN FET, each for example constructed of one or more metals (e.g., titanium, aluminum, nickel, or gold). A first conductive terminal is a gate terminal 112 formed along the AlGaN barrier layer 108, thereby separated from the GaN layer 106 by the AlGaN barrier layer 108. A second conductive terminal is a source terminal 114, formed in a first direction laterally away from the gate terminal 112 and having a portion extending through both the passivation layer 110 and the AlGaN barrier layer 108 and contacting the GaN layer 106. The source terminal 114 also includes a source field plate 114FP, which extends laterally from the source terminal 114 and over the gate terminal 112 and is separated from that gate terminal 112 by a portion of the passivation layer 110. A third conductive terminal is a drain terminal 116, formed in a second direction, opposite the first direction, laterally away from the gate terminal 112 and having a portion extending through both the passivation layer 110 and the AlGaN barrier layer 108 and contacting the GaN layer 106. In operation, the GaN FET does not have P/N junction operation as in the case of MOSFETs, but instead the heterojunction between the AlGaN barrier layer 108 and the GaN layer 106 forms a two-dimensional electron gas (2DEG) in a portion of the GaN layer 106 proximate the AlGaN barrier layer 108, at least in a region 118 between the source terminal 114 and the drain terminal 116. The 2DEG has very high charge carrier density and mobility, in which current flows between the source and drain terminals 114, 116 under the proper electrical conditions.

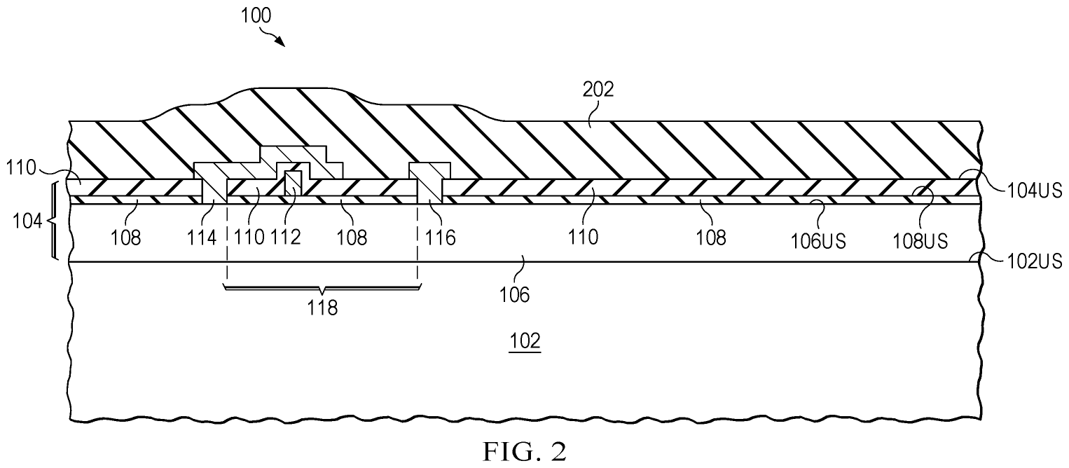

In FIG. 2, a second PMD layer 202 is formed over the FIG. 1 structure and thereby, at least in part, aligned along a plane (e.g., along an upper surface 104US of the layer stack 104). In an example, the second PMD layer 202 is conformal, and it may include silicon nitride (SiN) or silicon dioxide (SiO₂). Alternatively, the second PMD layer 202 may include plural layers, for example, a first layer of SiN followed by a second layer of SiO₂. The second PMD layer 202 (or its layers) may be formed by plasma enhanced chemical vapor deposition (PECVD) or by a high density plasma (HDP) deposition, for example to use relatively low temperature (e.g., at or below 300° C.) to avoid degradation to the conductive terminals (which may also be referred to as contact terminals). The second PMD layer 202 may have a thickness in a range from 1 μm to 5 μm, and it may provide dielectric isolation between source and drain potentials and to reduce capacitive coupling during operation of the GaN FET.

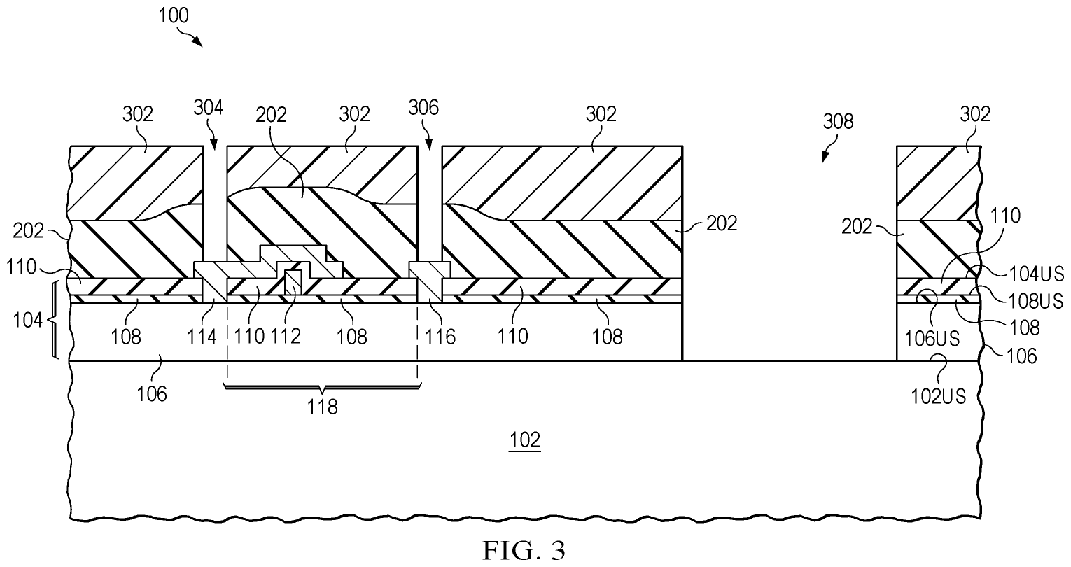

In FIG. 3, a mask 302 (e.g., photoresist) is formed over the FIG. 2 structure, and the mask 302 is patterned and etched in desired positions to form a first hole 304 through the second PMD layer 202 and to the source terminal 114, a second hole 306 through the second PMD layer 202 and to the drain terminal 116, and a third hole 308 through the second PMD layer 202 and the layer stack 104, to the substrate 102. The third hole 308 may have the same, or a larger lateral width (e.g., diameter), than either of the first and second holes 304 and 306. For reasons shown below, in the illustrated example the lateral width of the third hole 308 is at least twice as large as the lateral width of either of the first hole 304 or the second hole 306, although its lateral width could be up to five times or greater than the lateral width of either of the first hole 304 or the second hole 306. For example, the lateral width of the third hole 308 may be in a range from 2.0 μm to 10 μm, while the lateral width of each of the first hole 304 and the second hole 306 may be in a range from 0.2 μm to 0.8 μm.

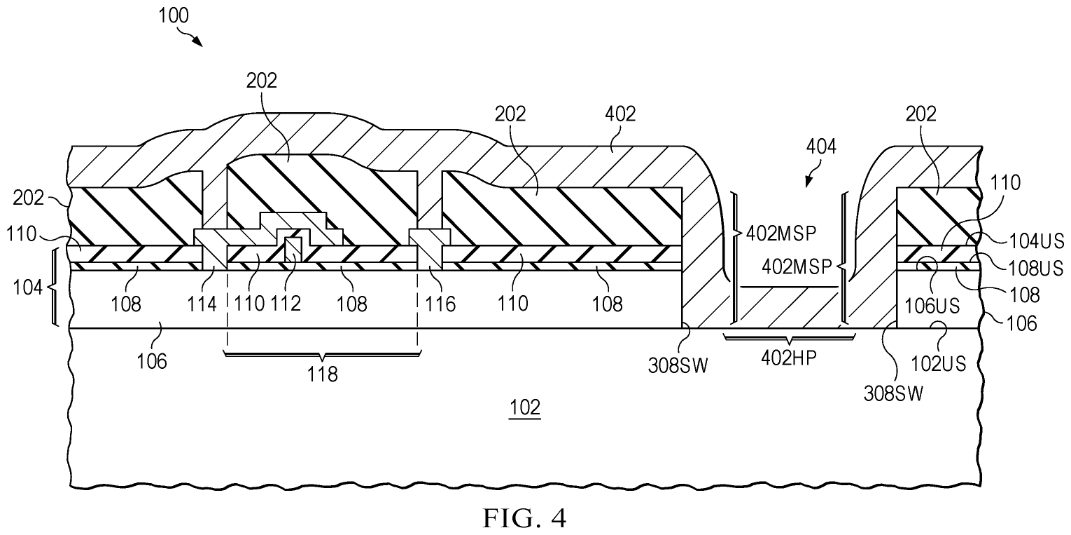

The first, second, and third holes 304, 306, and 308 may be formed in one or more steps. In one example, all of the first, second, and third holes 304, 306, and 308 are concurrently formed in a same etch step—e.g., using the patterned mask 302 as shown in FIG. 3. In another example, the first and second holes 304 and 306, having a same lateral width (i.e., in the y-direction of the cross-sectional drawings), are formed in one etch step, while the third hole 308, having a different lateral width than the first and second holes 304 and 306, is formed in a separate step. In this additional example, the mask 302 may be formed and patterned as a first mask with openings only for forming the first and second holes 304 and 306, after which a second mask is formed and patterned with an opening for forming only the third hole 308. While not shown, at a different x-y plane than illustrated in FIG. 4 (i.e., at a different z-dimension), the mask 302 may be also patterned and etched to provide for the formation of an additional hole through the second PMD 202 and aligned with the gate 112, so as to allow for formation of a contact to the gate 112.

In FIG. 4, the mask 302 has been removed, and a conformal interconnect or contact metal layer 402 is formed over the remaining FIG. 3 structure. In some examples, the metal layer 402 includes an adhesion layer (e.g., titanium), a barrier layer (e.g., titanium nitride) on the adhesion layer, and tungsten on the barrier layer. The thickness of the metal layer 402 is sufficient to fill the first and second holes 304 and 306. In contrast, and due to the relatively larger diameter of the third hole 308 being at least twice as wide as the smaller-diameter first and second holes 304 and 306, the metal layer 402 aligns along the inner sidewalls 308SW and bottom of the third hole 308, but leaves a void area 404 between the metalized portions along the inner sidewalls 308SW. Particularly, the metal layer 402 forms metal sidewall portions 402MSP along the respective inner sidewalls 308SW, so that each of the metal sidewall portions 402MSP has a first outward side contacting the second PMD layer 202, and a second inward side facing the remaining void area 404. The metal layer 402 also forms a horizontal portion 402HP extending along the bottom of the third hole 308, that is along a portion of the upper surface 102US, and between the metal sidewall portions 402MSP.

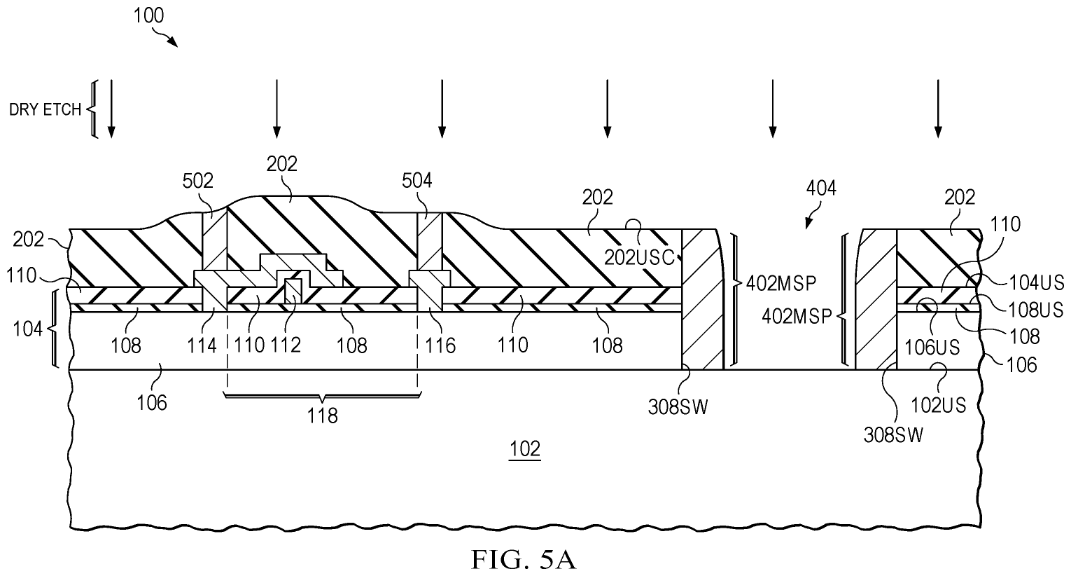

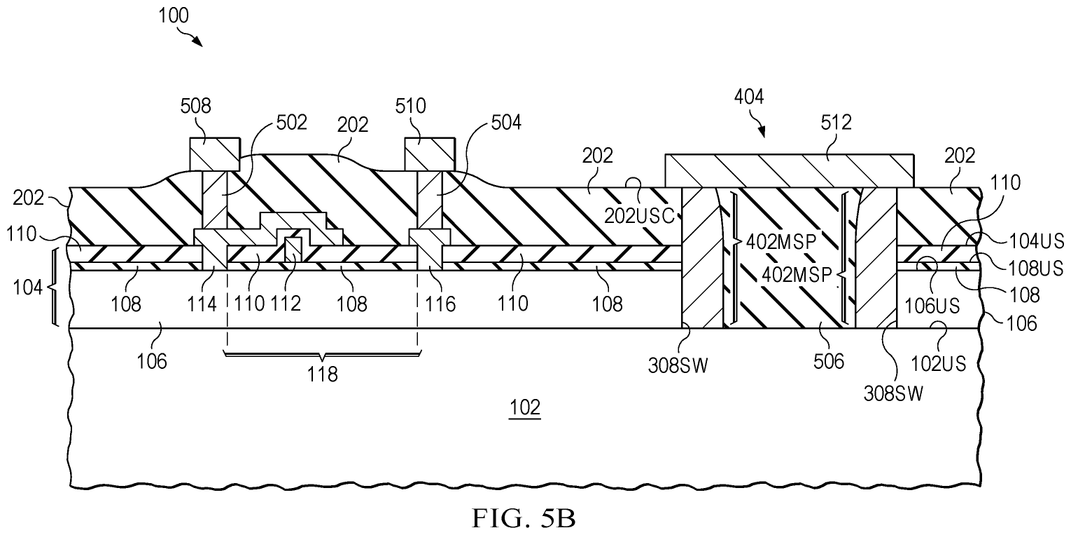

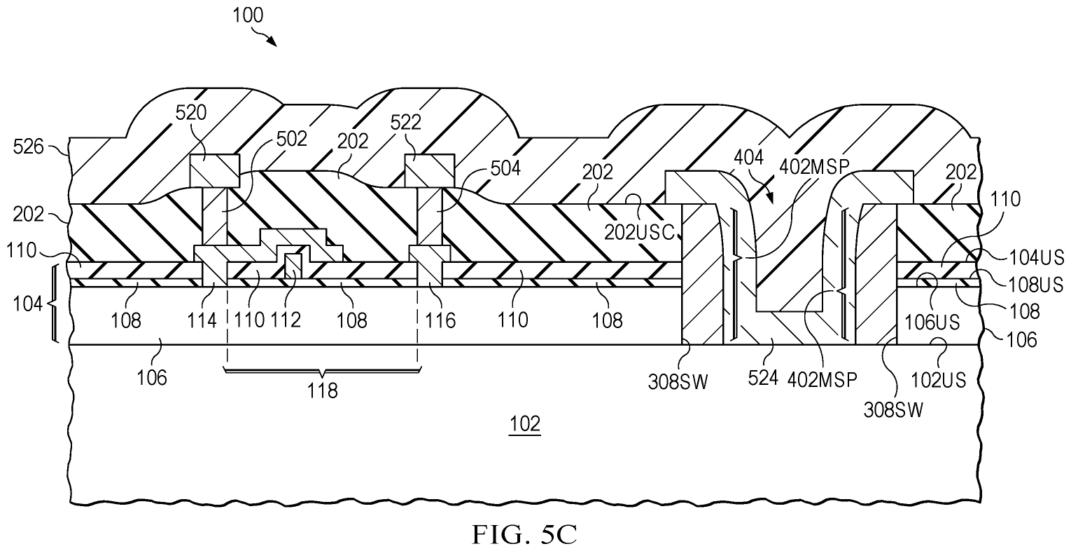

FIGS. 5A and 5B illustrate a first alternative process sequence following FIG. 4. In FIG. 5A, an etchback (e.g., dry etch) is performed on the FIG. 4 structure, so as to remove generally lateral portions of the conformal interconnect metal layer 402. The dry etch may involve reactive ion etching (RIE) or plasma etching. Following the etch, the non-lateral portions of the conformal interconnect metal layer 402 remain as metal contacts, including a first metal contact 502 through the second PMD layer 202 (and what was the first hole 304) and contacting the source terminal 114 and a second metal contact 504 through the second PMD layer 202 (and what was the second hole 306) and contacting the drain terminal 116. While not shown, at a different x-y plane than illustrated at a different z-dimension, an additional metal contact also may be formed to the gate 112, provided a hole was previously formed through the second PMD layer 202 and thereafter filled with the conformal interconnect metal layer 402. Additionally, due to the directional nature of the etch, the horizontal portion 402HP of the metal layer 402 is removed from below the void area 404, while the metal sidewall portions 402MSP remain. Accordingly, the top of the first contact 502, the second contact 504, and each of the metal sidewall portions 402MSP aligns along a conformal upper surface 202USC of the PMD layer 202.

In FIG. 5B, a third PMD layer 506 is formed in the void area 404, between the metal sidewall portions 402MSP and also in contact with a portion of the upper surface 102US. For example, the third PMD layer 506 may be formed by forming a dielectric layer over the entire FIG. 5A structure and then etching it such that only the portion of the dielectric layer filling the third void area 404 remains. Accordingly, while in FIG. 4 each of the metal sidewall portions 402MSP has a second inward side facing the void area 404, after the dielectric formation in FIG. 5B, each such second inward side faces and contacts the third PMD layer 506 (while the other side of each contact (e.g., the metal sidewall portions 402MSP) contacts the second PMD layer 202).

Next, a metal layer, sometimes referred to as metal-1, is formed over the structure, and patterned and etched to leave remaining metal portions, including a first metal portion 508 and a second metal portion 510. The first metal portion 508 contacts, and is in electrical communication with, the first metal contact 502, thereby providing a conductive path to the source terminal 114. The second metal portion 510 contacts, and is in electrical communication with, the second metal contact 504, thereby providing a conductive path to the drain terminal 116. The metal-1 layer etch also leaves a third metal portion 512. The third metal portion 512 contacts the metal sidewall portions 402MSP, thereby providing a conductive path to the substrate 102.

Additional processing steps may follow once the structure of FIG. 5B is complete, for example a next step may include the formation of an intermetal dielectric layer (IMD) above the remaining portions of the metal-1 layer, after which other metal layers are formed in connection with the formation or connections of other devices and the like. Note by the completion of FIG. 5B, however, that substrate contact is already in place, for example using in part the same process steps already in place for the contact formation—e.g., forming the first metal contact 502 and the second metal contact 504. Further, based on geometries selected, the width of the FIG. 3 holes 304, 306, and 308 may be selected, along with the thickness of the FIG. 4 metal layer 402, such that the resulting metal sidewall portions 402MSP provide contact to the substrate 102 with a larger lateral thickness than the first and second metal contacts 502 and 504 providing respective contact to the source terminal 114 and the drain terminal 116. As a result, favorable conductive attributes (e.g., resistance) may be achieved using the described process and with the resultant structure. Additionally, in the illustrated example, there is no need for IMD planarization relative to substrate contact, and the substrate contact may be complete without interaction with backend and packaging process steps.

FIG. 5C is a cross-section view representing an alternative process sequence to FIG. 5B. In FIG. 5C, a metal layer (e.g., metal-1) is formed over the structure (e.g., the structure shown in FIG. 5A), and patterned and etched to leave remaining metal portions, including a first metal portion 520 and a second metal portion 522. The first metal portion 520 contacts, and is in electrical communication with, the first metal contact 502, thereby providing a conductive path to the source terminal 114. The second metal portion 522 contacts, and is in electrical communication with, the second metal contact 504, thereby providing a conductive path to the drain terminal 116. The metal-1 layer etch also leaves a third metal portion 524. In an example, the third metal portion 524 is conformal to the metal sidewall portions 402MSP, thereby forming a U-shaped structure extending in part horizontally along the conformal upper surface 202USC and an upper surface of a metal sidewall portion 402MSP, in part vertically along a side of the metal sidewall portion 402MSP, and in part horizontally extending along the bottom of the void area 404, that is along a portion of the upper surface 102US, and between the metal sidewall portions 402MSP.

Next in FIG. 5C, a dielectric layer 526, such as an intermetal dielectric (IMD), is formed over the structure, which also fills the remaining portion of the void 404 that exists between the vertical portions of the U-shaped third metal portion 524. Accordingly, after the dielectric formation in FIG. 5C, each inward facing side (facing the void 404) of the third metal portion 524 contacts the dielectric layer 526, while each laterally outer facing side of the third metal portion 524 contacts a sidewall portion 402MSP.

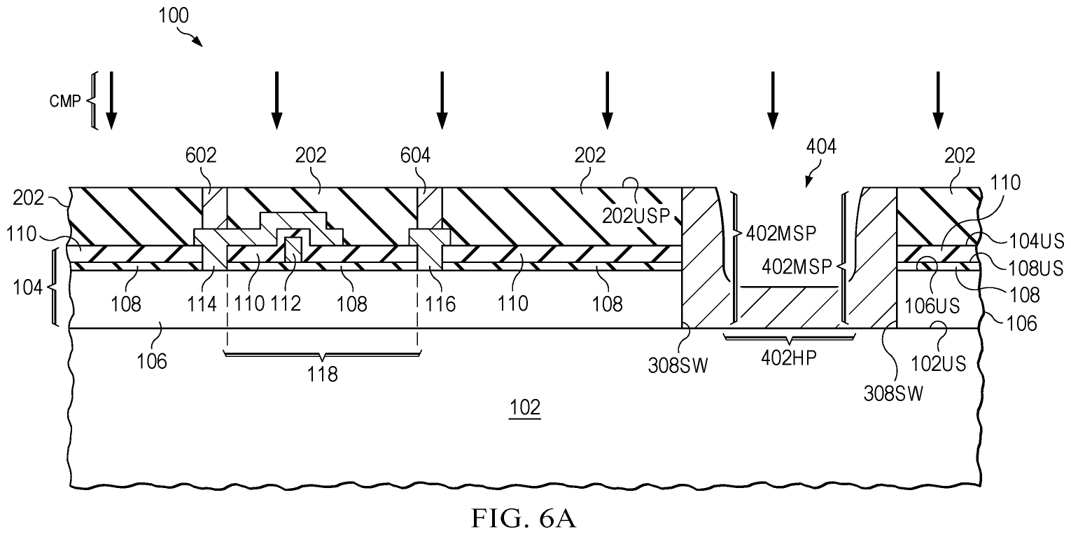

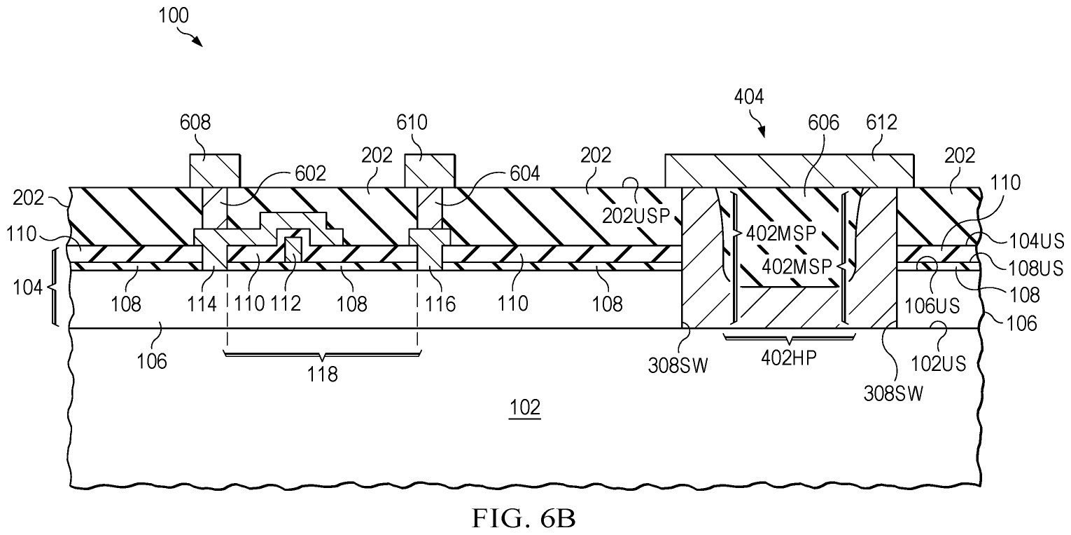

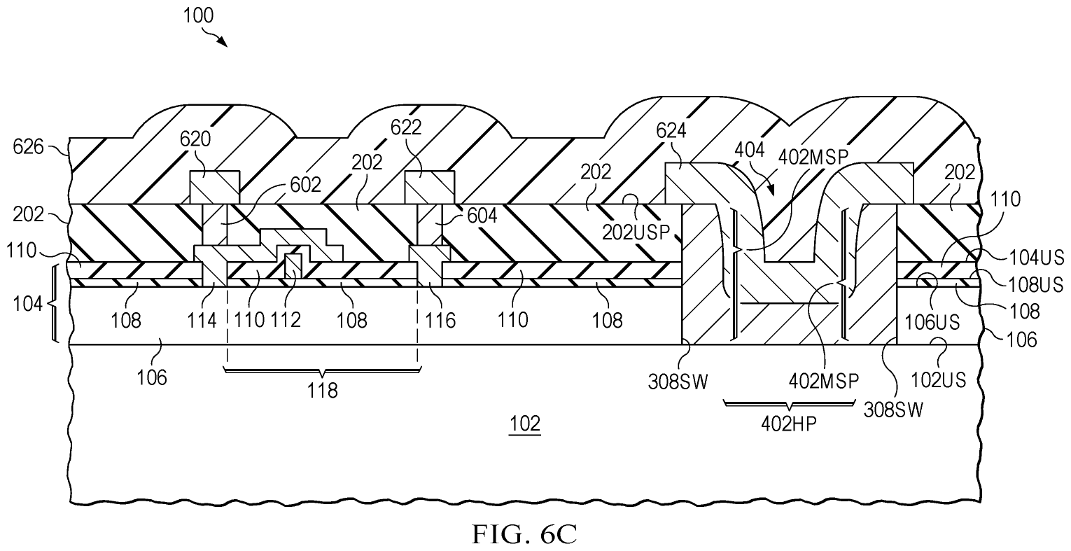

FIGS. 6A and 6B illustrate a second alternative process sequence following FIG. 4. In FIG. 6A, a planarizing process (e.g., chemical mechanical planarization (CMP)) is performed on the FIG. 4 structure. The planarizing process is continued downward to remove material across horizontal planes of the structure in a top-down fashion, and is stopped at the point shown in FIG. 6A, that is, once the portions of the metal layer 402 above the second PMD layer 202 are removed. The planarization leaves a smooth and flat horizontal top edge for the structure. Following the planarization, the non-lateral portions of the conformal interconnect metal layer 402 remain as metal contacts, including a first metal contact 602 through what was the first hole 304 and contacting the source terminal 114 and a second metal contact 604 through what was the second hole 306 and contacting the drain terminal 116. Again while not shown, at a different x-y plane in the z-dimension than illustrated, an additional metal contact also may be formed to the gate terminal 112. Additionally, due to the top-down nature of the planarization as applied in FIG. 6A, then the FIG. 4 horizontal portion 402HP remains in the bottom of the void area 404 and along the upper surface 102US, thereby providing a generally U-shaped conductor in what was previously the third hole 308 and with a conductive path provided by the horizontal portion 402HP between the remaining metal sidewall portions 402MSP. Further, the addition of the horizontal portion 402HP as part of the entire conductive area provides lower contact resistance due to a larger contact area to the substrate 102.

Further, also resulting from the planarization, the top of the first contact 602, the second contact 604, and each of the metal sidewall portions 402MSP aligns along a common plane, namely, along the planar upper surface 202USP of the PMD layer 202.

In FIG. 6B, a third PMD layer 606 is formed within the interior of the U-shaped conductor that includes the horizontal portion 402HP and the remaining metal sidewall portions 402MSP. For example, the third PMD layer 606 may be formed by forming a dielectric layer over the entire FIG. 6A structure and then etching it such that only the portion of the dielectric layer filling the interior of the U-shaped conductor remains. In some examples, after forming a dielectric layer over the entire FIG. 6A structure a CMP can be performed such that only the portion of the dielectric layer filling the interior of the U-shaped conductor remains.

Next, a metal layer (e.g., metal-1), is formed over the structure, and patterned and etched to leave remaining metal portions, including a first metal portion 608 and a second metal portion 610. The first metal portion 608 contacts and is in electrical communication with the first metal contact 602, thereby providing a conductive path to the source terminal 114. The second metal portion 610 contacts and is in electrical communication with the second metal contact 604, thereby providing a conductive path to the drain terminal 116. The metal-1 layer etch also leaves a third metal portion 612. The third metal portion 612 contacts the metal sidewall portions 402MSP, thereby providing a conductive path to the substrate 102.

Similar to the earlier description regarding FIG. 5B, after the FIG. 6B structure is formed, additional processing steps also may follow. Also as described above, by the completion of FIG. 6B, the substrate contact is already in place, for example using in part the same process steps already in place for the contact formation (e.g., the first metal contact 602, the second metal contact 604). Moreover, FIG. 6B illustrates that selected geometries may result in the sidewall portions 402MSP and the horizontal portion 402HP, having a larger cross-sectional thickness than the first and second metal contacts 602 and 604, with those cross-sectional thicknesses being in the x-dimension for the sidewall portions 402MSP and in y-dimension for the horizontal portion 402HP.

FIG. 6C is a cross-section view representing an alternative process sequence to FIG. 6B. In FIG. 6C, a metal layer (e.g., metal-1) is formed over the structure (e.g., the structure shown in FIG. 6A), and patterned and etched to leave remaining metal portions, including a first metal portion 620 and a second metal portion 622. The first metal portion 620 contacts, and is in electrical communication with, the first metal contact 602, thereby providing a conductive path to the source terminal 114. The second metal portion 622 contacts, and is in electrical communication with, the second metal contact 604, thereby providing a conductive path to the drain terminal 116. The metal-1 layer etch also leaves a third metal portion 624. In an example, the third metal portion 624 is conformal to the metal sidewall portions 402MSP and to the horizontal portion 402HP, thereby forming a U-shaped structure extending in part horizontally along the planar upper surface 202USP and an upper surface of a metal sidewall portion 402MSP, in part vertically along a side of the metal sidewall portion 402MSP, and in part horizontally extending along the top of the horizontal portion 402HP.

Next in FIG. 6C, a dielectric layer 626, such as an IMD, is formed over the structure, which also fills the remaining portion of the void 404 that exists between the vertical portions of the U-shaped third metal portion 624. Accordingly, after the dielectric formation in FIG. 6C, each inward facing side (facing the void 404) of the third metal portion 624 contacts the dielectric layer 626, each laterally outer facing side of the third metal portion 624 contacts a sidewall portion 402MSP, and the lower horizontal surface of the third metal portion 624 contacts an upper surface of the horizontal portion 402HP.

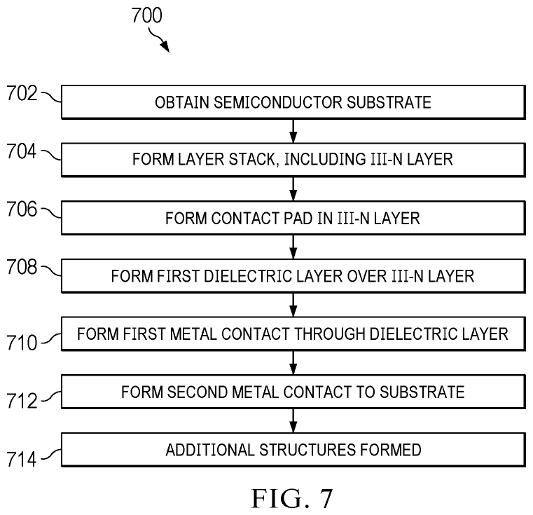

FIG. 7 is a flow diagram of an example method 700 summarizing various of the above-described steps for manufacturing the semiconductor device 100, for example as shown in FIGS. 5B and 6B. The method 700 begins in a step 702, in which the FIG. 1 semiconductor substrate 102 is obtained. The semiconductor substrate 102, at this stage, may be a bare wafer or may have one or more semiconductor features already formed on it. The semiconductor substrate 102 also includes one or more areas, or one or more electrical structures adjacent to such an area, in which it is desirable to form semiconductor or silicon or III-N including devices, for example such as a transistor. Next, in a step 704, a layer stack is formed over the semiconductor substrate. For example, the layer stack may include the GaN layer 106 along the upper surface 102US, along with one or more of the aluminum gallium nitride (AlGaN) barrier layer 108 and the passivation layer 110. Next, in a step 706, at least one contact pad is formed in the III-N layer. For example, the contact pad may be either of the source terminal 114 or the drain terminal 116. Next, in a step 708, a first dielectric layer is formed over the III-N layer. For example, the first dielectric layer may be the second PMD layer 202 (FIG. 2). Next, in a step 710, a first metal contact is formed through the first dielectric layer. For example, the first metal contact may be either of the first metal contact 502 or the second metal contact 504 (FIG. 5A) or the first metal contact 602 or second metal contact 604 (FIG. 6A). Next, in a step 712, a second metal contact is formed contacting the semiconductor substrate, with a first side of the second metal contact contacting the first dielectric layer and a second side of the second metal contact contacting a second dielectric layer. For example, the second metal contact may be a metal sidewall portion 402MSP (FIG. 5B; FIG. 6B). Lastly, a step 714 generally represents that, after the step 712, additional structures may be formed in connection with the transistor (and possibly other devices and interconnections to this and other devices) associated with the semiconductor substrate 102.

From the above, one skilled in the art should appreciate that examples are provided for semiconductor fabrication, for example with respect to an IC that includes a III-N layer and contact to a substrate that is proximate (e.g., below, in a lateral view) the III-N layer. Such examples may provide various benefits, some of which are described above and including still others. Still additional modifications are possible in the described examples, and other examples are possible, within the scope of the following claims.

What is claimed is:

1. A semiconductor device, comprising:
a semiconductor substrate;
a III-N semiconductor layer over the semiconductor substrate;
a contact pad on the III-N semiconductor layer;
a first dielectric layer over the III-N semiconductor layer;
a first metal contact through the first dielectric layer and contacting the contact pad; and
a second metal contact, including a first side contacting the first dielectric layer and a second side contacting a second dielectric layer, and contacting the semiconductor substrate.

2. The semiconductor device of claim 1 wherein the second dielectric layer has a thickness greater than a thickness of the first dielectric layer.

3. The semiconductor device of claim 1:
wherein the first dielectric layer is aligned along a first plane;
wherein the III-N semiconductor layer is aligned along a second plane; and
wherein the second dielectric layer extends from the first plane to the second plane.

4. The semiconductor device of claim 1 and further comprising a third metal contact, including a first side contacting the first dielectric layer and a second side contacting the second dielectric layer, and contacting the semiconductor substrate.

5. The semiconductor device of claim 4 and further comprising a metal member extended along the substrate and contacting the second metal contact and the third metal contact.

6. The semiconductor device of claim 4 and further comprising a metal member extended across the first dielectric layer and the second dielectric layer and contacting the second metal contact and the third metal contact.

7. The semiconductor device of claim 4 wherein a surface of the first metal contact, a surface of the second metal contact, a surface of the third metal contact, and a surface of the first dielectric layer align along a common plane.

8. The semiconductor device of claim 4 wherein a surface of the first metal contact, a surface of the second metal contact, a surface of the third metal contact, and a surface of the first dielectric layer align along a conformal surface of the first dielectric layer.

9. The semiconductor device of claim 1:
wherein the first metal contact has a first length through the first dielectric layer and a first width orthogonal to the length; and
wherein the second metal contact has a second length parallel to the first length and a second width orthogonal to the second length; and
wherein the second width is greater than the first width.

10. The semiconductor device of claim 9 wherein the second width is from two to five times the first width.

11. The semiconductor device of claim 1 wherein a surface of the first metal contact, a surface of the second metal contact, and a surface of the first dielectric layer align along a common plane.

12. The semiconductor device of claim 1 wherein the III-N semiconductor layer comprises gallium nitride.

13. A semiconductor device, comprising:
a semiconductor substrate;
a III-N semiconductor layer over the semiconductor substrate;
a transistor source contact pad on the III-N semiconductor layer;
a transistor drain contact pad on the III-N semiconductor layer;
a first dielectric layer over each of the III-N semiconductor layer, the transistor source pad, and the transistor drain pad;
a first metal contact through the first dielectric layer and contacting the transistor source contact pad;
a second metal contact through the first dielectric layer and contacting the transistor drain contact pad; and
a third metal contact, including a first side contacting the first dielectric layer and a second side contacting a second dielectric layer differing from the first dielectric layer, and contacting the semiconductor substrate.

14. The semiconductor device of claim 13 and further comprising a fourth metal contact, including a first side contacting the first dielectric layer and a second side contacting the second dielectric layer, and contacting the semiconductor substrate.

15. The semiconductor device of claim 14 wherein the second dielectric layer contacts the semiconductor substrate and extends between the first side of the third metal contact and the first side of the fourth metal contact.

16. The semiconductor device of claim 14 and further comprising a metal member extending between the third metal contact and the fourth metal contact.

17. The semiconductor device of claim 14 and further comprising a metal member contacting the semiconductor substrate and extending between the third metal contact and the fourth metal contact.

18. A method of forming a semiconductor device, comprising:
forming a III-N semiconductor layer over a semiconductor substrate;
forming a contact pad on the III-N semiconductor layer;
forming a first dielectric layer over the III-N semiconductor layer;
forming a first metal contact through the first dielectric layer and contacting the contact pad; and
forming a second metal contact contacting the semiconductor substrate, the second metal contact including a first side contacting the first dielectric layer and a second side contacting a second dielectric layer.

19. The method of claim 18 wherein the second dielectric layer comprises a conformal non-planarized dielectric layer, and further comprising:
forming a third metal contact contacting the semiconductor substrate, the third metal contact including a first side contacting the first dielectric layer and a second side contacting the conformal non-planarized dielectric layer.

20. The method of claim 18, and further comprising:
forming a third metal contact contacting the semiconductor substrate, the third metal contact including a first side contacting the first dielectric layer and a second side contacting the second dielectric layer; and
after forming a third metal contact, planarizing an upper surface of the first metal contact, the second metal contact, the third metal contact, and the second dielectric layer.

21. The method of claim 18:
wherein forming the first metal contact comprises forming the first metal contact through a hole with a first width in the first dielectric layer; and
wherein forming the second metal contact comprises forming the second metal contact through a second hole with a second width in the first dielectric layer, wherein the second width is at least twice as wide as the first width.
